(19) United States
(12) Patent Application Publication
(10) Pub. No.: US 2022/0416117 A1
(43) Pub. Date: Dec. 29, 2022

(54) LED Display Convenient to Be Repaired, and Repair Method Thereof

(71) Applicant: CHONGQING KONKA PHOTOELECTRIC TECHNOLOGY RESEARCH INSTITUTE CO., LTD., Chongqing (CN)

(72) Inventors: Pengyue ZHANG, Chongqing (CN); Ruilin XU, Chongqing (CN); Chia-Hua HUANG, Chongqing (CN)

(21) Appl. No.: 17/424,879

(22) PCT Filed: Mar. 18, 2020
(86) PCT No.: PCT/CN2020/080019

§ 371 Date: Jul. 21, 2021

(51) Int. Cl. H01L 33/00; H01L 25/075; H01L 33/62

(52) U.S. Cl. CPC H01L 33/0095; H01L 25/0753; H01L 33/62; H01L 2933/0066

(57) ABSTRACT

The present disclosure relates to the technical field of light-emitting diodes, in particular to an LED display convenient to be repaired and a repair method thereof. The LED display comprises: a planarization layer and a circuit layer, the planarization layer being provided with first and second previously prepared electrodes for being connected to a standby LED chip; the first and second previously prepared electrodes are respectively in communication with a thin-film transistor and a power line ground terminal which are in the circuit layer; a groove is provided in the planarization layer, the first and second previously prepared electrodes respectively extend along a sidewall of the groove, and are respectively connected to first and second contact electrodes at the bottom of the groove, an LED COB is accommodated in the groove, and two electrodes in the LED COB are respectively connected to the first and second contact electrodes; and the top of the LED COB does not exceed the opening of the groove.

### TECHNICAL FIELD

The present disclosure relates to the technical field of light emitting diodes, and in particular, to an LED display convenient to be repaired and a method for repairing an LED display.

### BACKGROUND

Micro light emitting diodes (Micro LEDs), i.e. the miniaturization and matritization of the light emitting diodes, have advantages with respect to stability, service life and operating temperature, and at the same time also inherit the advantages of low power consumption, color saturation, fast reaction speed, high contrast, etc. of LEDs, and have great application prospect.

Making a display screen from a micro light emitting diode is a future mainstream development direction of a display device. In the existing process, after chips are transferred to the display backplane, each LED chip on the display backplane needs to be detected, and when it is found that there is a damaged LED chip or an LED chip having a poor contact, it needs to be replaced. In the existing repairing and replacement process, the damaged LED chip needs to be picked up from the display backplane, and then a good LED chip is re-bonded at the corresponding position. The process is troublesome, which is disadvantageous for the rapid production of products.

### SUMMARY

In order to overcome the above defects, the object of the present disclosure is to provide an LED display that facilitates rapid replacement of a light emitting diode chip and a repairing and replacement method thereof.

The object of the present disclosure is achieved by the following technical solutions:

the present disclosure discloses an LED display convenient to be repaired, comprising:

a display backplane, the display backplane comprising a substrate, a circuit layer and a planarization layer which are provided in sequence, wherein the surface of one side of the planarization layer away from the circuit layer is provided with a first previously prepared electrode and a second previously prepared electrode, and the first previously prepared electrode and the second previously prepared electrode are used for being connected to a standby LED chip;

through through-holes in the planarization layer, the first previously prepared electrode and the second previously prepared electrode are respectively in communication with a thin-film transistor and a power line ground terminal which are in the circuit layer;

a groove is provided on the planarization layer, and the groove is provided between the first previously prepared electrode and the second previously prepared electrode;

the first previously prepared electrode and the second previously prepared electrode respectively extend along the sidewall of the groove towards the bottom of the groove, so as to form a first electrode extension portion and a second electrode extension portion; the first electrode extension portion and the second electrode extension portion are respectively connected to a first contact electrode and a second contact electrode at the bottom of the groove, an LED chip on board (COB) is accommodated in the groove, and the LED COB is a flip-type LED chip;

a first COB electrode and a second COB electrode in the LED COB are respectively welded with the first contact electrode and the second contact electrode; and the top of the LED COB does not exceed the opening of the groove.

In some embodiments of the present disclosure, there is a gap between the sidewall of the groove and the LED COB.

In some embodiments of the present disclosure, an insulating material is filled between an outer sidewall of the LED COB, the first electrode extension portion and the second electrode extension portion.

In some embodiments of the present disclosure, a distance from the surface of one side of the second previously prepared electrode away from the planarization layer to the surface of the circuit layer is a second distance; a distance from the surface of one side of the second previously prepared electrode away from the planarization layer to the surface of the circuit layer is a second distance; and the first distance is equal to the second distance.

In some embodiments of the present disclosure, a distance from the surface of one side of the second previously prepared electrode away from the planarization layer to the surface of the circuit layer is a second distance; a distance from the surface of one side of the second previously prepared electrode away from the planarization layer to the surface of the circuit layer is a second distance; and the first distance is unequal to the second distance.

In some embodiments of the present disclosure, the standby LED chip comprises: a standby chip light-emitting layer; the two sides of the standby chip light-emitting layer are respectively connected to a first standby chip semiconductor layer and a second standby chip semiconductor layer, one side of the first standby chip semiconductor layer away from the light-emitting layer and one side of the second standby chip semiconductor layer away from the light-emitting layer are respectively connected to a first standby chip electrode and a second standby chip electrode, the first standby chip electrode and the second standby chip electrode are respectively used for being welded with the first previously prepared electrode and the second previously prepared electrode; and the epitaxial part of the standby LED chip is provided on the surface of the LED COB.

In some embodiments of the present disclosure, there is a gap between the epitaxial part of the LED COB, the first previously prepared electrode and the second previously prepared electrode.

In some embodiments of the present disclosure, the bottom of the planarization layer is provided with a thin-film transistor contact point and a power line ground terminal contact point, the thin-film transistor contact point is in communication with the first previously prepared electrode through a first through hole, the power line ground terminal contact point is in communication with the second previously prepared electrode through a second through hole, and both the first through hole and the second through hole are filled with a conductive material.

In some embodiments of the present disclosure, there is one or more grooves in the planarization layer, and an LED COB is accommodated in each groove.

The present disclosure discloses a method for repairing the LED display convenient to be repaired, comprising:

after it is detected that the LED COB on the display backplane is damaged, fusing the first electrode extension portion and the second electrode extension portion on the groove sidewall in which the LED COB is located, so that the first previously prepared electrode and the second previously prepared electrode are respectively disconnected from the first contact electrode and the second contact electrode;

placing a standby LED chip above the LED COB, and aligning a first standby chip electrode and a second standby chip electrode in the standby LED chip with the first previously prepared electrode and the second previously prepared electrode respectively; and

bonding the first standby chip electrode and the second standby chip electrode in the standby LED chip to the first previously prepared electrode and the second previously prepared electrode, respectively.

In the LED display of the present disclosure, the LED COB is provided in the groove of the planarization layer, and a previously prepared electrode is provided on the surface of the planarization layer. Therefore, when it is detected that the LED COB is damaged during the production process, the replacement can be completed by cutting off the electrode extension portion between the previously prepared electrode and the contact electrode, and directly bonding the standby LED chip to the standby electrode. There is no need to pick up the LED COB from the display backplane, so that the bonding of the standby LED chip can be achieved above the original position, greatly improving the production efficiency of the product and facilitating rapid production of the product.

### BRIEF DESCRIPTION OF THE DRAWINGS

For ease of illustration, the present disclosure is described in details with reference to the following preferred embodiments and drawings.

FIG. 1 is a schematic structural sectional diagram of an LED display before being repaired according to embodiment 1 of the present disclosure;

FIG. 2 is an exploded structural schematic diagram of an LED display before being repaired according to embodiment 1 of the present disclosure;

FIG. 3 is a schematic structural sectional diagram of a repaired LED display according to embodiment 1 of the present disclosure;

FIG. 4 is a schematic structural sectional diagram of an LED display before being repaired according to embodiment 2 of the present disclosure;

FIG. 5 is a schematic structural sectional diagram of a repaired LED display according to embodiment 2 of the present disclosure;

FIG. 6 is a schematic diagram illustrating an operation flow of a method for repairing an LED display according to embodiment 3 of the present disclosure;

FIG. 7 is a schematic diagram illustrating the operation principle of step S101 in embodiment 3 of the present disclosure; and

FIG. 8 is a schematic diagram illustrating the operation principle of step S102 in embodiment 3 of the present disclosure.

### DETAILED DESCRIPTION OF THE EMBODIMENTS

To make the object, technical solution and advantages of the present disclosure clearer, the present disclosure is further described in details with reference to the accompanying drawings and embodiments.

It should be understood that the embodiments described herein are only intended to explain the present disclosure, but not to limit the present disclosure.

In the description of the present disclosure, it should be noted that, azimuth or positional relationships indicated by terms such as ‘center’, ‘longitudinal’, ‘transverse’, ‘length’, ‘width’, ‘thickness’, ‘upper’, ‘lower’, ‘front’, ‘rear’, ‘left’, ‘right’, ‘vertical’, ‘horizontal’, ‘top’, ‘bottom’, ‘inner’, ‘outer’, ‘clockwise’, ‘counterclockwise’ and so on, are based on the azimuth or positional relationships illustrated in the drawings, which are only to facilitate description of the present disclosure and simplify the description, but not to indicate or imply that the device or components must have a specific azimuth, or be constructed or operated in the specific azimuth, which thus cannot be understood as a limitation to the present disclosure. In addition, the terms ‘first’, ‘second’ and so on are only used for descriptive purpose, and should not be interpreted as indicating or implying the significance or implicitly indicating the number of the indicated technical features. Hence, the features defined by the ‘first’, ‘second’ may clearly indicate or impliedly comprise one or more of the features. Unless stated otherwise, the term ‘a plurality of’ means two or more in the description of the present disclosure.

Unless otherwise defined, the terms such as ‘mounted’, ‘connected’ and ‘connection’ should be broadly understood, for instance, may refer to fixed connection and may also refer to detachable connection or integral connection, may be a mechanical connection, or a electrical connection; may be a direct connection or an indirect connection through intermediate medium, or may be an internal communication between two elements or an interaction relationship between two elements. For those skilled in the art, specific meaning of such terms in the present disclosure can be understood according to particular circumstances or applications.

### Embodiment 1

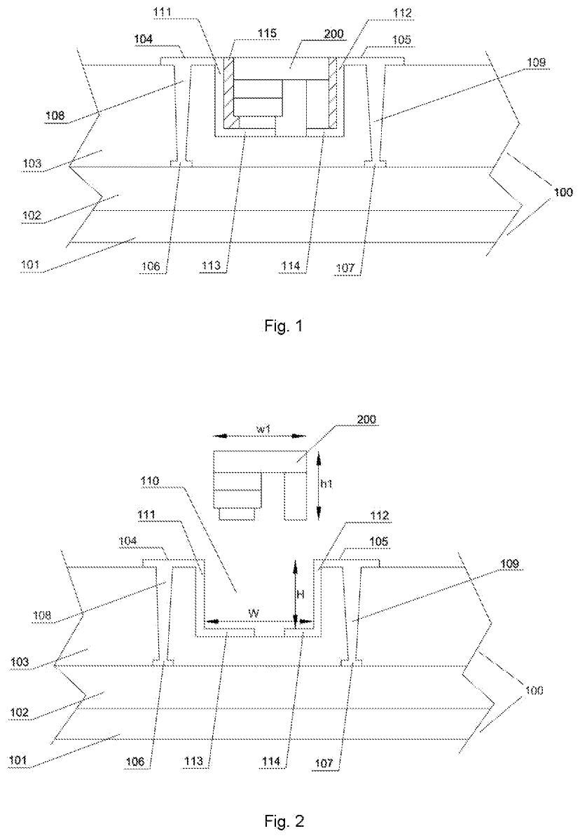

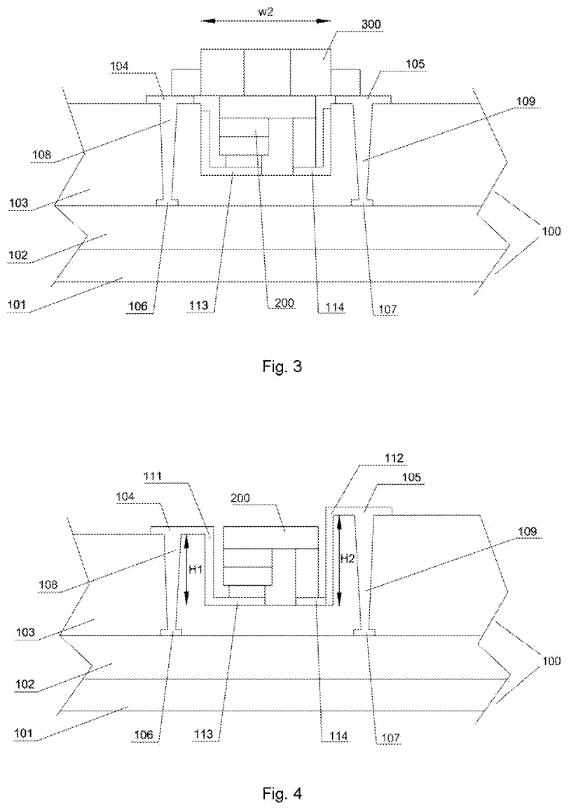

With an embodiment, the LED display convenient to be repaired of the present disclosure will be described in details below, referring to FIGS. 1 to 3, including:

A display backplane 100, the display backplane 100 comprises a substrate 101, a circuit layer 102 and a planarization layer 103 which are arranged from bottom to top, wherein the substrate 101 can comprise a transparent glass material, such as silicon dioxide (SiO2). The substrate 101 may also include a transparent plastic material, such as polyethersulfone (PES), polyacrylate (PAR), polyetherimide (PEI), polyethylene terephthalate (PEN), polyethylene terephthalate (PET), polyphenylene sulfide (PPS), polyarylate, polyimide, polycarbonate (PC), triacetate cellulose (TAC), or cellulose propionate (CAP) and other organic materials. The circuit layer 102 includes a driving circuit for driving an LED chip, such as a thin-film transistor (TFT), a gate line and a signal line. The planarization layer 103 covers the circuit layer 102, and can eliminate the step difference on the circuit layer 102, so as to planarize the circuit layer. The planarization layer 103 may include an organic material, such as polymethyl methacrylate (PMMA) or polystyrene (PS), a polymer derivative having a phenol group, a propylene-based polymer, an imide-based polymer, an aryl ether-based polymer, an amide-based polymer, a fluorine-based polymer, a para-xylyl polymer, a vinyl alcohol-based polymer, or any combination thereof.

A first previously prepared electrode 104 and a second previously prepared electrode 105 are provided on an upper surface of the planarization layer 103, and the first previously prepared electrode 104 and the second previously prepared electrode 105 are configured to be connected to a first standby chip electrode 301 and a second standby chip electrode 302 in the standby LED chip 300. The standby LED chip 300 comprises a standby chip light-emitting layer 303, a first standby chip semiconductor layer 304 and a second standby chip semiconductor layer 305. The two sides of the standby chip light-emitting layer 303 are respectively connected to a first standby chip semiconductor layer 304 and a second standby chip semiconductor layer 305. The outer sides of the first standby chip semiconductor layer 304 and the second standby chip semiconductor layer 305 are respectively connected to the first standby chip electrode 301 and the second standby chip electrode 302.

The bottom of the planarization layer 103 is provided with a thin-film transistor contact point 106 and a power line ground terminal contact point 107, the thin-film transistor contact point 106 is in communication with the first standby electrode 104 through a first through hole 108, and the power line ground terminal contact point 107 is in communication with the second standby electrode 105 through a second through hole 109, and the first through hole 108 and the second through hole 109 are both filled with a conductive material.

One or more grooves 110 are provided in the planarization layer 103, the first previously prepared electrode 104 and the second previously prepared electrode 105 are respectively provided on two sides of the groove 110, and a distance from the surface of one side of the first standby electrode 104 away from the planarization layer 103 to the surface of the circuit layer 102 is a first distance H1; a distance from the surface of one side of the second standby electrode 105 away from the planarization layer 103 to the surface of the circuit layer 102 is a second distance H2; and the first distance H1 is equal to the second distance H2; in addition, the first previously prepared electrode 104 and the second previously prepared electrode 105 extend along the sidewall of the groove 110 towards the bottom of the groove 110 to form a first electrode extension portion 111 and a second electrode extension portion 112, and the first electrode extension portion 111 and the second electrode extension portion 112 are respectively connected to the first contact electrode 113 and the second contact electrode 114 at the bottom of the groove 110. The first previously prepared electrode 104, the first electrode extension portion 111 and the first contact electrode 113 are integrally formed. The second previously prepared electrode 105, the second electrode extension portion 112 and the second contact electrode 114 are integrally formed. The first previously prepared electrode 104, the first electrode extension portion 111, the first contact electrode 113, the second previously prepared electrode 105, the second electrode extension portion 112, the second contact electrode 114 and the conductive material are made from materials such as aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) or copper (Cu).

An LED COB 200 is accommodated in the groove 110. The LED COB 200 comprises a first COB electrode 201 and a second COB electrode 202 which are separated from each other. The upper end of the second COB electrode 202 is connected to the second COB semiconductor layer 205. The first COB electrode 201 is connected to the second COB semiconductor layer 205 through the first COB semiconductor layer 203 and the COB light-emitting layer 204 sequentially. The first COB electrode and the second COB electrode 202 in the LED COB 200 are respectively connected to the first contact electrode 113 and the second contact electrode 114. The width W of the groove 110 is greater than the width w1 of the LED COB 200, that is, there is a gap between the sidewall of the groove 110 and the LED COB 200. The height h1 of the top of the LED COB 200 does not exceed the height H of the opening of the groove 110. Therefore, the groove 110 can fully accommodate the LED COB 200, so as to prevent the LED COB 200 from protruding from the surface of the display backplane 100, so that the standby LED chip 300 can be smoothly mounted on the display backplane 100, without taking out the LED COB 200. The width w2 of the epitaxial part of the standby LED chip 300 is not greater than the width W of the groove 110, so that there is a gap between the epitaxial part, the first previously prepared electrode 104 and the second previously prepared electrode 105.

Furthermore, an insulating material 115 is filled between the outer sidewall of the LED COB 200, the first electrode extension portion 111 and the second electrode extension portion 112. This effectively prevents the occurrence of short-circuiting phenomenon due to a contact between the LED COB 200, the first electrode extension portion 111 and the second electrode extension portion 112.

In the present embodiment, the LED COB 200 and the standby LED chip 300 are both micron (μm) LED chips.

### Embodiment 2

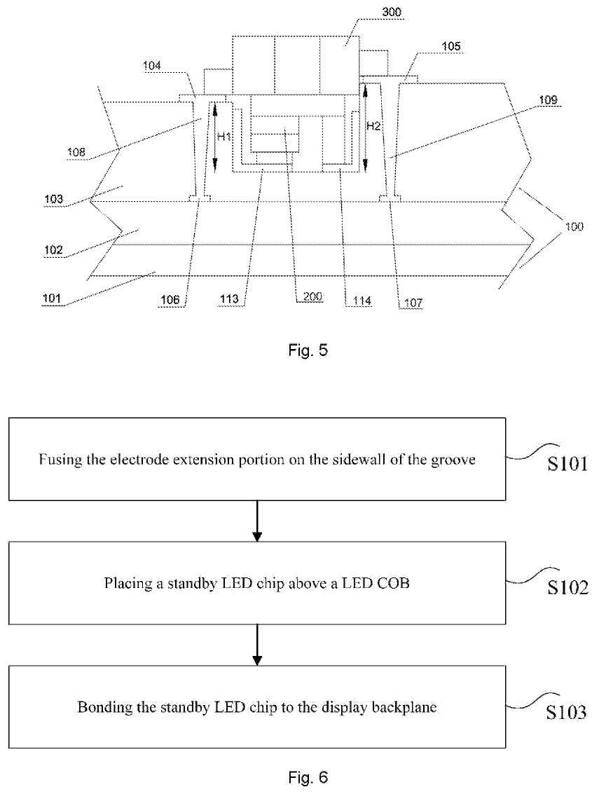

With another embodiment, the LED display convenient to be repaired of the present disclosure will be described in details below, referring to FIGS. 4 to 5, including:

a display backplane 100, the display backplane 100 comprising a substrate 101, a circuit layer 102 and a planarization layer 103 which are arranged from bottom to top, wherein the substrate 101 can comprise a transparent glass material, such as silicon dioxide (SiO2). The substrate 101 may also include a transparent plastic material, such as polyethersulfone (PES), polyacrylate (PAR), polyetherimide (PEI), polyethylene terephthalate (PEN), polyethylene terephthalate (PET), polyphenylene sulfide (PPS), polyarylate, polyimide, polycarbonate (PC), triacetate cellulose (TAC), or cellulose propionate (CAP) and other organic materials. The circuit layer 102 includes a driving circuit for driving an LED chip, such as a TFT, a gate line and a signal line. The planarization layer 103 covers the circuit layer 102, and can eliminate the step difference on the circuit layer 102, so as to planarize the circuit layer. The planarization layer 103 may include an organic material, such as polymethyl methacrylate (PMMA) or polystyrene (PS), a polymer derivative having a phenol group, a propylene-based polymer, an imide-based polymer, an aryl ether-based polymer, an amide-based polymer, a fluorine-based polymer, a para-xylyl polymer, a vinyl alcohol-based polymer, or any combination thereof.

A first previously prepared electrode 104 and a second previously prepared electrode 105 are provided on an upper surface of the planarization layer 103, and the first previously prepared electrode 104 and the second previously prepared electrode 105 are configured to be connected to a first standby chip electrode 301 and a second standby chip electrode 302 in the standby LED chip 300. The standby LED chip 300 comprises a standby chip light-emitting layer 303, a first standby chip semiconductor layer 304 and a second standby chip semiconductor layer 305. The two sides of the standby chip light-emitting layer 303 are respectively connected to a first standby chip semiconductor layer 304 and a second standby chip semiconductor layer 305. The outer sides of the first standby chip semiconductor layer 304 and the second standby chip semiconductor layer 305 are respectively connected to the first standby chip electrode 301 and the second standby chip electrode 302.

The bottom of the planarization layer 103 is provided with a thin-film transistor contact point 106 and a power line ground terminal contact point 107, the thin-film transistor contact point 106 is in communication with the first standby electrode 104 through a first through hole 108, and the power line ground terminal contact point 107 is in communication with the second standby electrode 105 through a second through hole 109, and the first through hole 108 and the second through hole 109 are both filled with a conductive material.

One or more grooves 110 are provided in the planarization layer 103, the first previously prepared electrode 104 and the second previously prepared electrode 105 are respectively provided on two sides of the groove 110, and a distance from the surface of one side of the first standby electrode 104 away from the planarization layer 103 to the surface of the circuit layer 102 is a first distance H1; a distance from the surface of one side of the second standby electrode 105 away from the planarization layer 103 to the surface of the circuit layer 102 is a second distance H2; and the first distance H1 is not equal to the second distance H2. In the present embodiment, the surface heights of the planarization layer 103 on both sides of the opening of the groove 110 may be set to be different. The thickness of the first previously prepared electrode 104 and the thickness of the second previously prepared electrode 105 may be set to be different, so as to set the horizontal height H1 of the first previously prepared electrode 104 to be different from the horizontal height H2 of the second previously prepared electrode 105. In this embodiment, specifically, the horizontal height H1 of the first previously prepared electrode 104 is lower than the horizontal height H2 of the second previously prepared electrode 105, which not only contributes to the clamping of the standby LED chip 300, but also prevents the abnormal working of the standby LED chip 300 cause by inverted placement of the first standby chip electrode 301 and the second standby chip electrode 302 in the standby LED chip 300. In addition, the first previously prepared electrode 104 and the second previously prepared electrode 105 extend along the sidewall of the groove 110 towards the bottom of the groove 110 to form a first electrode extension portion 111 and a second electrode extension portion 112, and the first electrode extension portion 111 and the second electrode extension portion 112 are respectively connected to the first contact electrode 113 and the second contact electrode 114 at the bottom of the groove 110. The first previously prepared electrode 104, the first electrode extension portion 111 and the first contact electrode 113 are integrally formed. The second previously prepared electrode 105, the second electrode extension portion 112 and the second contact electrode 114 are integrally formed. The first previously prepared electrode 104, the first electrode extension portion 111, the first contact electrode 113, the second previously prepared electrode 105, the second electrode extension portion 112, the second contact electrode 114 and the conductive material are made from materials such as aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) or copper (Cu).

An LED COB 200 is accommodated in the groove 110. The LED COB 200 comprises a first COB electrode 201 and a second COB electrode 202 which are separated from each other. The upper end of the second COB electrode 202 is connected to the second COB semiconductor layer 205. The first COB electrode 201 is connected to the second COB semiconductor layer 205 through the first COB semiconductor layer 203 and the COB light-emitting layer 204 sequentially. The first COB electrode and the second COB electrode 202 in the LED COB 200 are respectively connected to the first contact electrode 113 and the second contact electrode 114. The width W of the groove 110 is greater than the width w1 of the LED COB 200, that is, there is a gap between the sidewall of the groove 110 and the LED COB 200. The height h1 of the top of the LED COB 200 does not exceed the height H of the opening of the groove 110. Therefore, the groove 110 can fully accommodate the LED COB 200, so as to prevent the LED COB 200 from protruding from the surface of the display backplane 100, so that the standby LED chip 300 can be smoothly mounted to the display backplane 100, without taking out the LED COB 200. The width w2 of the epitaxial part of the standby LED chip 300 is not greater than the width W of the groove 110, so that there is a gap between the epitaxial part, the first previously prepared electrode 104 and the second previously prepared electrode 105.

Furthermore, an insulating material 115 is filled between the outer sidewall of the LED COB 200, the first electrode extension portion 111 and the second electrode extension portion 112. This effectively prevents the occurrence of short-circuiting phenomenon due to a contact between the LED COB 200, the first electrode extension portion 111 and the second electrode extension portion 112.

In the present embodiment, the LED COB 200 and the standby LED chip 300 are both micron (μm) LED chips.

### Embodiment 3

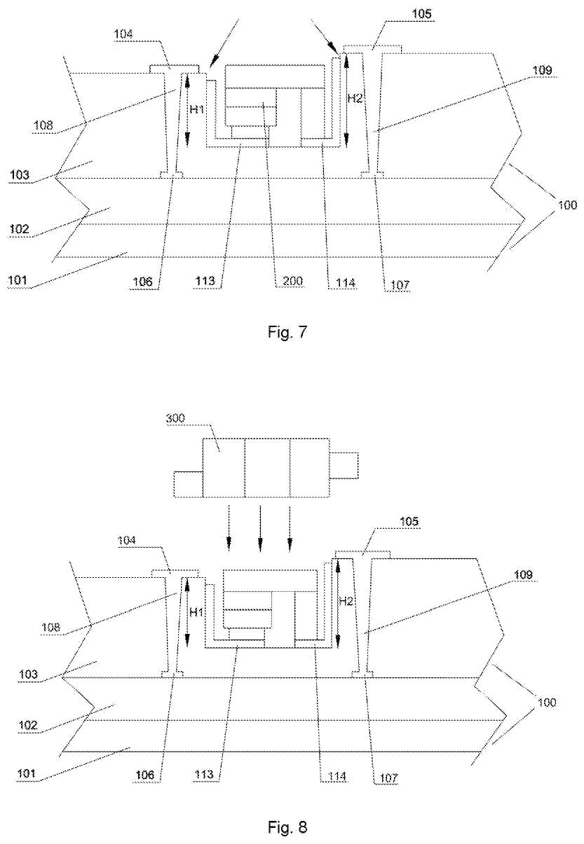

Hereinafter, with an embodiment, the method for repairing the LED display of the present disclosure will be described in details below, referring to FIGS. 6 to 9, including:

S101: fusing the electrode extension portion on the sidewall of the groove upon detection that the LED COB 200 on the display backplane 100 is damaged, the first electrode extension portion 111 and the second electrode extension portion 112 on the sidewall of the groove 110 where the LED COB 200 is located are respectively fused by laser heating or using an array repair device, so that the first previously prepared electrode 104 and the second previously prepared electrode 105 are respectively disconnected from the first contact electrode 113 and the second contact electrode 114, accordingly, the LED COB 200 in the groove 110 is disconnected from the circuit layer;

S102, placing a standby LED chip above a LED COB

the standby LED chip 300 is placed above the LED COB 200, and the first standby chip electrode 301 and the second standby chip electrode 302 in the standby LED chip 300 are aligned with the first previously prepared electrode 104 and the second previously prepared electrode 105 on the display backplane 100 respectively; preferably, in the present embodiment, the horizontal height H1 of the first previously prepared electrode 104 is different from the horizontal height H2 of the second previously prepared electrode 105, so that the heights of the first standby chip electrode 301 and the second standby chip electrode 302 in the standby LED chip 300 are also different, which can quickly identify the two previously prepared electrodes, and effectively avoid the occurrence of reversed placement of the electrodes;

S103, bonding the standby LED chip to the display backplane

the first standby chip electrode 301 and the second standby chip electrode 302 in the standby LED chip 300 are respectively bonded to the first previously prepared electrode 104 and the second previously prepared electrode 105; the standby LED chip 300 receives electrical signals through the first and second standby electrodes 105 on the display backplane 100 for normal driving; furthermore, since the electrical connection between the LED COB 200 and the circuit layer has been disconnected, the LED COB 200 will not work.

In the descriptions of the specification, descriptions with reference to terms “an embodiment”, “some embodiments”, “exemplary embodiment”, “example”, “exemplary example”, “some examples” or the like refer to that exemplary characteristics, structures, materials or features described in combination with the embodiment or the example are included in at least one embodiment or example of the present disclosure. In the present specification, schematic representations of the terms above do not necessarily refer to the same embodiments or examples. In addition, described characteristics, structures, materials or features may be combined in any one or more embodiments or examples in a proper manner.

The above are only preferred embodiments of the present invention, which are not described for limiting the present invention, it is noted that various modifications, alterations and improvements made by persons skilled in this art within the spirits and principles of the present disclosure should also be deemed to be embraced in the scope of protection of the present disclosure.

What is claimed is:

1. An LED display convenient to be repaired, comprising:
a display backplane, the display backplane comprising a substrate, a circuit layer and a planarization layer which are provided in sequence, wherein the surface of one side of the planarization layer away from the circuit layer is provided with a first previously prepared electrode and a second previously prepared electrode, and the first previously prepared electrode and the second previously prepared electrode are used for being connected to a standby LED chip;
through through-holes in the planarization layer, the first previously prepared electrode and the second previously prepared electrode are respectively in communication with a thin-film transistor and a power line ground terminal which are in the circuit layer;
a groove is provided on the planarization layer, and the groove is provided between the first previously prepared electrode and the second previously prepared electrode;
the first previously prepared electrode and the second previously prepared electrode respectively extend along the sidewall of the groove towards the bottom of the groove, so as to form a first electrode extension portion and a second electrode extension portion; the first electrode extension portion and the second electrode extension portion are respectively connected to a first contact electrode and a second contact electrode at the bottom of the groove, an LED chip on board (COB) is accommodated in the groove, and the LED COB is a flip-type LED chip;
a first COB electrode and a second COB electrode in the LED COB are respectively welded with the first contact electrode and the second contact electrode; and
the top of the LED COB does not exceed the opening of the groove.

2. The LED display convenient to be repaired according to claim 1, wherein there is a gap between the sidewall of the groove and the LED COB.

3. The LED display convenient to be repaired according to claim 2, wherein an insulating material is filled between an outer sidewall of the LED COB, the first electrode extension portion and the second electrode extension portion.

4. The LED display convenient to be repaired according to claim 3, wherein a distance from the surface of one side of the first previously prepared electrode away from the planarization layer to the surface of the circuit layer is a first distance; a distance from the surface of one side of the second previously prepared electrode away from the planarization layer to the surface of the circuit layer is a second distance; and the first distance is equal to the second distance.

5. The LED display convenient to be repaired according to claim 3, wherein a distance from the surface of one side of the first previously prepared electrode away from the planarization layer to the surface of the circuit layer is a first distance; a distance from the surface of one side of the second previously prepared electrode away from the planarization layer to the surface of the circuit layer is a second distance; and the first distance is unequal to the second distance.

6. The LED display convenient to be repaired according to claim 5, wherein the standby LED chip comprises: a standby chip light-emitting layer; the two sides of the standby chip light-emitting layer are respectively connected to a first standby chip semiconductor layer and a second standby chip semiconductor layer, one side of the first standby chip semiconductor layer away from the light-emitting layer and one side of the second standby chip semiconductor layer away from the light-emitting layer are respectively connected to a first standby chip electrode and a second standby chip electrode, the first standby chip electrode and the second standby chip electrode are respectively used for being welded with the first previously prepared electrode and the second previously prepared electrode, and the epitaxial part of the standby LED chip is provided on the surface of the LED COB.

7. The LED display convenient to be repaired according to claim 6, wherein there is a gap between the epitaxial part of the LED COB and the first previously prepared electrode and the second previously prepared electrode.

8. The LED display convenient to be repaired according to claim 7, wherein the bottom of the planarization layer is provided with a thin-film transistor contact point and a power line ground terminal contact point, the thin-film transistor contact point is in communication with the first previously prepared electrode through a first through hole, the power line ground terminal contact point is in communication with the second previously prepared electrode through a second through hole, and both the first through hole and the second through hole are filled with a conductive material.

9. The LED display convenient to be repaired according to claim 8, wherein there is one or more grooves in the planarization layer, and an LED COB is accommodated in each groove.

10. A method for repairing an LED display convenient to be repaired according to claim 1, comprising:
after it is detected that the LED COB on the display backplane is damaged, fusing the first electrode extension portion and the second electrode extension portion on the sidewall of the groove in which the LED COB is located, so that the first previously prepared electrode and the second previously prepared electrode are respectively disconnected from the first contact electrode and the second contact electrode;
placing a standby LED chip above the LED COB, and aligning a first standby chip electrode and a second standby chip electrode in the standby LED chip with the first previously prepared electrode and the second previously prepared electrode respectively; and
bonding the first standby chip electrode and the second standby chip electrode in the standby LED chip to the first previously prepared electrode and the second previously prepared electrode, respectively.

11. The method for repairing an LED display convenient to be repaired according to claim 10, the step fusing the first electrode extension portion and the second electrode extension portion on the sidewall of the groove in which the LED COB is located comprising:
fusing the first electrode extension portion and the second electrode extension portion on the sidewall of the groove in which the LED COB is located by laser heating.

12. The method for repairing an LED display convenient to be repaired according to claim 10, the step fusing the first electrode extension portion and the second electrode extension portion on the sidewall of the groove in which the LED COB is located comprising:
fusing the first electrode extension portion and the second electrode extension portion on the sidewall of the groove in which the LED COB is located by using an array repair device.

13. The method for repairing an LED display convenient to be repaired according to claim 10, wherein a horizontal height of the first previously prepared electrode is different from a horizontal height of the second previously prepared electrode.

14. A system for repairing an LED display convenient to be repaired, wherein the system comprises: an LED display convenient to be repaired as claim 1, and a standby LED chip, wherein the standby LED chip comprises: a standby chip light-emitting layer; the two sides of the standby chip light-emitting layer are respectively connected to a first standby chip semiconductor layer and a second standby chip semiconductor layer, one side of the first standby chip semiconductor layer away from the light-emitting layer and one side of the second standby chip semiconductor layer away from the light-emitting layer are respectively connected to a first standby chip electrode and a second standby chip electrode, the first standby chip electrode and the second standby chip electrode are respectively used for being welded with the first previously prepared electrode and the second previously prepared electrode.

15. The system for repairing an LED display convenient to be repaired according to claim 14, the epitaxial part of the standby LED chip is provided on the surface of the LED COB.

16. The system for repairing an LED display convenient to be repaired according to claim 14, wherein there is a gap between the epitaxial part of the LED COB and the first previously prepared electrode and the second previously prepared electrode.

17. The system for repairing an LED display convenient to be repaired according to claim 14, wherein the bottom of the planarization layer is provided with a thin-film transistor contact point and a power line ground terminal contact point, the thin-film transistor contact point is in communication with the first previously prepared electrode through a first through hole, the power line ground terminal contact point is in communication with the second previously prepared electrode through a second through hole.

18. The system for repairing an LED display convenient to be repaired according to claim 17, both the first through hole and the second through hole are filled with a conductive material.
